(19) United States
(12) Patent Application Publication
(10) Pub. No.: US 2026/0260856 A1
(43) Pub. Date: Sep. 3, 2026

(54) SUBSTRATE FIXING DEVICE

(71) Applicant: SHINKO ELECTRIC INDUSTRIES CO., LTD., Nagano-shi (JP)

(72) Inventors: Keita Sato, Nagano (JP); Keisuke Kasahara, Nagano (JP); Yusuke Ide, Nagano (JP); Yuta Naito, Nagano (JP)

(21) Appl. No.: 19/550,561

(22) Filed: Feb. 26, 2026

(30) Foreign Application Priority Data
Feb. 28, 2025 (JP) 2025-031244

(51) Int. Cl. H01J 37/32; H10P 72/72

(52) U.S. Cl. CPC H01J 37/32724; H10P 72/722; H01J 2237/334

(57) ABSTRACT

A substrate fixing device includes: a base plate having a first adhesive surface; an electrostatic chuck having a second adhesive surface; and an adhesive layer for bonding the first adhesive surface of the base plate and the second adhesive surface of the electrostatic chuck, in which the electrostatic chuck includes a base body having a third adhesive surface forming a portion of the second adhesive surface and having a recessed portion provided therein, an electronic component accommodated in the recessed portion, and a resin layer configured to seal the electronic component in the recessed portion and having a fourth adhesive surface forming another portion of the second adhesive surface, and a temperature corresponding to an extreme value of a loss tangent within a temperature range of −150° C. or higher and 250° C. or lower of the resin layer is −70° C. or lower.

### CROSS-REFERENCE TO RELATED APPLICATIONS

This application claims priority from Japanese Patent Application No. 2025-031244 filed on Feb. 28, 2025, the contents of which are incorporated herein by reference.

### TECHNICAL FIELD

The present disclosure relates to a substrate fixing device.

### BACKGROUND ART

In the related art, a film formation apparatus and a plasma etching apparatus that are used when manufacturing a semiconductor device have a stage for accurately holding a wafer such as a silicon wafer in a vacuum treatment chamber. As such a stage, for example, a substrate fixing device is suggested which adsorbs and holds a wafer by an electrostatic chuck mounted on a base plate.

The substrate fixing device includes a base plate, an electrostatic chuck mounted on the base plate, and an adhesive layer for bonding the base plate and the electrostatic chuck. An electrode for adsorbing the substrate, and a heating element for controlling a temperature of the substrate, which is an object to be adsorbed, are embedded in the electrostatic chuck.

### CITATION LIST

### Patent Literature

Patent Literature 1: JP2024-030799A
Patent Literature 2: JP2023-071003A

### SUMMARY OF INVENTION

In the substrate fixing device, non-uniformity in heat-generation density may occur on a substrate placement surface of the electrostatic chuck that adsorbs the substrate. The non-uniformity in heat-generation density causes non-uniformity in temperature on the substrate. The non-uniformity in substrate temperature causes non-uniformity in etching rate in a plasma etching apparatus, for example, and thus becomes a factor that reduces the yield of semiconductor devices. Therefore, an improvement in uniformity of temperature on the substrate placement surface of the electrostatic chuck is required.

An object of the present disclosure is to provide a substrate fixing device capable of improving uniformity of temperature on a substrate placement surface.

According to an aspect of the present disclosure, there is provided a substrate fixing device including: a base plate having a first adhesive surface; an electrostatic chuck configured to adsorb and hold a substrate and having a substrate placement surface on which the substrate is mounted and a second adhesive surface opposite to the substrate placement surface; and an adhesive layer for bonding the first adhesive surface of the base plate and the second adhesive surface of the electrostatic chuck, in which the electrostatic chuck includes a base body having a third adhesive surface forming a portion of the second adhesive surface and having a recessed portion provided therein, an electronic component accommodated in the recessed portion, and a resin layer configured to seal the electronic component in the recessed portion and having a fourth adhesive surface forming another portion of the second adhesive surface, and a temperature corresponding to an extreme value of a loss tangent within a temperature range of −150° C. or higher and 250° C. or lower of the resin layer is −70° C. or lower.

According to the present disclosure, the uniformity of temperature on the substrate placement surface can be improved.

### BRIEF DESCRIPTION OF DRAWINGS

FIG. 1 is a cross-sectional view illustrating a substrate fixing device according to an embodiment.

FIG. 2 is a diagram showing a relationship between a measurement temperature and a loss tangent.

### DESCRIPTION OF EMBODIMENTS

The present inventors have conducted intensive studies in order to investigate a cause of non-uniformity in heat-generation density occurring on a substrate placement surface of a substrate fixing device of the related art. As a result, it was found that a recessed portion for accommodating an electronic component used for temperature control or the like is formed in an electrostatic chuck, the electronic component is accommodated in the recessed portion, and the recessed portion is filled with a resin layer, and when the substrate fixing device is used in a low-temperature environment of −40° C. or lower, cracks may occur in the resin layer. In addition, it was also found that cracks occurring in the resin layer lower the uniformity of temperature transfer characteristics and cause the non-uniformity in heat-generation density. Further, it was also found that, as a cause of cracks occurring in the resin layer, the modulus of the resin layer increases rapidly in the low-temperature environment of −40° C. or lower, and a large stress acts on the resin layer when the electrostatic chuck thermally contracts. Therefore, based on these findings, the present inventors have conducted further intensive studies in order to reduce the stress acting on the resin layer in the low-temperature environment, and have arrived at the following embodiments.

Embodiments of the present disclosure will be described in detail below with reference to the accompanying drawings. Note that, in the specification and drawings, the components having substantially the same functional configuration are denoted by the same reference signs, and redundant descriptions thereof are omitted.

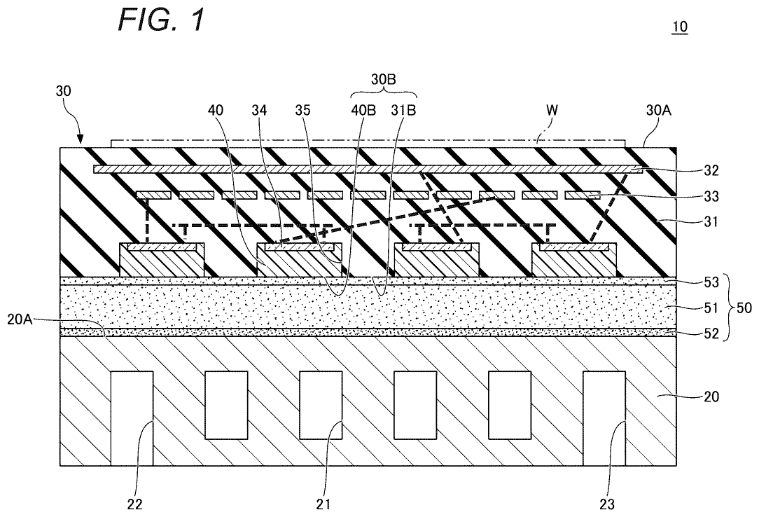

Embodiments relate to a substrate fixing device. FIG. 1 is a cross-sectional view illustrating a substrate fixing device according to an embodiment.

As illustrated in FIG. 1, a substrate fixing device 10 includes a base plate 20, an electrostatic chuck 30, and an adhesive layer 50. The base plate 20 is a base member for mounting the electrostatic chuck 30. The electrostatic chuck 30 is a part that adsorbs and holds a substrate W, which is an object to be adsorbed. The electrostatic chuck 30 is, for example, a temperature adjustment device that adjusts a temperature of the substrate W. Note that the substrate W is a silicon wafer, for example.

The base plate 20 is formed, for example, in a circular plate shape. A planar shape of the base plate 20 is circular, for example. A diameter of the base plate 20 is about 200 mm to 300 mm, for example. A thickness of the base plate 20 is about 20 mm to 50 mm, for example.

Examples of materials for the base plate 20 include metal materials such as aluminum and cemented carbide, and composite materials of these metal materials and ceramic materials. The base plate 20 may also be used, for example, as an electrode for controlling plasma. For example, by supplying a predetermined high-frequency power to the base plate 20, the energy for causing ions or the like in a generated plasma state to collide with the substrate W adsorbed on the electrostatic chuck 30 can be controlled, thereby effectively performing an etching process.

The base plate 20 has a first adhesive surface 20A (here, an upper surface). The first adhesive surface 20A is a surface that is bonded to the adhesive layer 50. The first adhesive surface 20A faces the electrostatic chuck 30. Here, the term “faces” in the present disclosure includes both a case where a member different from two parts is interposed between the two parts and a case where nothing is interposed between the two parts.

In the base plate 20, for example, a cooling channel 21 is provided. The cooling channel 21 has an introduction portion 22 provided at one end and a discharge portion 23 provided at the other end. The cooling channel 21 is connected to a cooling medium control device (not illustrated) provided outside the substrate fixing device 10, for example. The cooling medium control device introduces a cooling medium into the cooling channel 21 from the introduction portion 22, and discharges the cooling medium from the discharge portion 23. The cooling medium can be circulated in the cooling channel 21 to cool the base plate 20, thereby cooling the substrate W adsorbed on the electrostatic chuck 30. Note that, as the cooling medium, water, fluorine-based fluid, or the like may be used, for example. In addition to the cooling channel 21, a gas channel for introducing an inert gas to cool the substrate W adsorbed on the electrostatic chuck 30 may also be provided in the base plate 20.

The electrostatic chuck 30 is formed, for example, in a circular plate shape. A planar shape of the electrostatic chuck 30 is circular, for example. A diameter of the electrostatic chuck 30 may be the same as that of the base plate 20, or may be larger than that of the base plate 20, for example. In the present embodiment, the diameter of the electrostatic chuck 30 is the same as that of the base plate 20. The diameter of the electrostatic chuck 30 is about 200 mm to 300 mm, for example. A thickness of the electrostatic chuck 30 is about 1 mm to 10 mm, for example.

The electrostatic chuck 30 includes, for example, a base body 31, an electrostatic electrode 32 and a heating element 33 embedded in the base body 31, an electronic component 34, and a resin layer 40. The electrostatic chuck 30 has a substrate placement surface 30A (here, an upper surface) on which the substrate W is placed, and a second adhesive surface 30B (here, a lower surface) opposite to the substrate placement surface 30A. The substrate placement surface 30A and the second adhesive surface 30B are provided on opposite sides in a thickness direction (an upper-lower direction in the drawing) of the electrostatic chuck 30. For example, the substrate placement surface 30A and the second adhesive surface 30B are parallel to each other. The electrostatic chuck 30 is, for example, a Johnsen-Rahbek type electrostatic chuck. Note that the electrostatic chuck 30 may also be a Coulomb-type electrostatic chuck.

As a material for the base body 31, for example, a material with insulating properties may be exemplified. Examples of materials for the base body 31 include ceramics such as alumina, aluminum nitride, and silicon nitride, and organic materials such as silicone resin and polyimide resin. From viewpoints such as ease of availability, ease of machining, and relatively high resistance to plasma or the like, ceramics are preferable as materials for the base body 31. In particular, when the material of the base body 31 is aluminum nitride, since its thermal conductivity is large, such as about 15 W/(m·K) to 250 W/(m·K), it is preferable for reducing an in-plane temperature difference of the substrate W absorbed on the electrostatic chuck 30.

The base body 31 has a third adhesive surface 31B that forms a portion of the second adhesive surface 30B. A plurality of recessed portions 35 are provided in the third adhesive surface 31B. Each recessed portion 35 is formed to be recessed from the third adhesive surface 31B toward the substrate placement surface 30A. A depth of each recessed portion 35 is about 800 μm to 1000 μm, for example. A planar shape of each recessed portion 35 may be of any shape and any size. The planar shape of each recessed portion 35 is circular or elliptical, for example.

The electrostatic electrode 32 is an electrode for adsorbing the substrate W. The electrostatic electrode 32 is an electrode formed in a thin film shape. The electrostatic electrode 32 is embedded in the base body 31. The electrostatic electrode 32 is, for example, embedded in a portion located near the substrate placement surface 30A in the thickness direction of the base body 31. The electrostatic electrode 32 is arranged, for example, on a plane parallel to the substrate placement surface 30A. The electrostatic electrode 32 is electrically connected to an adsorption power supply (not illustrated) provided outside the substrate fixing device 10. When a predetermined voltage is applied from the adsorption power supply, the electrostatic electrode 32 generates an adsorption force by static electricity between the electrostatic electrode and the substrate W placed on the substrate placement surface 30A. This makes it possible to adsorb and hold the substrate W on the substrate surface 30A. The higher the voltage applied to the electrostatic electrode 32, the stronger the adsorption holding force in the electrostatic chuck 30. The electrostatic electrode 32 may be of a unipolar shape or a bipolar shape. Examples of materials for the electrostatic electrode 32 include tungsten (W) and molybdenum (Mo). Note that, in each drawing, one electrostatic electrode 32 is illustrated, but in actuality, a plurality of electrodes arranged on the same plane are included.

A plurality of heating elements 33 are used to heat the substrate W. The plurality of heating elements 33 are embedded in the base body 31. The plurality of heating elements 33 are embedded, for example, between the electrostatic electrode 32 and the second adhesive surface 30B in the thickness direction of the base body 31. The plurality of heating elements 33 are arranged, for example, on a plane parallel to the substrate placement surface 30A. Each heating element 33 is electrically insulated from the electrostatic electrode 32. Examples of materials for the heating element 33 include copper (Cu), tungsten, nickel (Ni), and constantan (an alloy of Cu, Ni, Mn, and Fe). A thickness of the heating element 33 is about 20 μm to 100 μm, for example. The plurality of heating elements 33 are arranged, for example, in a concentric pattern.

The plurality of heating elements 33 are electrically connected to a heating power supply (not illustrated) provided outside the substrate fixing device 10. The plurality of heating elements 33 generate heat, in response to a voltage applied from the heating power supply. The plurality of heating elements 33 heat the substrate placement surface 30A to a predetermined temperature. The heating elements 33 can heat the substrate placement surface 30A to about 250° C. to 300° C., for example.

The electronic component 34 is accommodated in the recessed portion 35. The electronic component 34 is provided on a bottom surface of the recessed portion 35. The electronic component 34 is electrically connected to, for example, the electrostatic electrode 32 or the heating element 33. In FIG. 1, wirings for electrically connecting the electronic component 34 to the electrostatic electrode 32 or the heating element 33 are shown by broken lines. The electronic component 34 is an electronic component used for temperature control of the substrate placement surface 30A, or the like, for example. Examples of the electronic component 34 include a diode, a capacitor, and a thermistor.

The resin layer 40 is provided in the recessed portion 35. The resin layer 40 is formed to seal the electronic component 34 accommodated in each recessed portion 35 and to fill the recessed portion 35, for example. The resin layer 40 has a fourth adhesive surface 40B that forms another portion of the second adhesive surface 30B. The second adhesive surface 30B of the electrostatic chuck 30 has the third adhesive surface 31B of the base body 31 and the fourth adhesive surface 40B of the resin layer 40. For example, the fourth adhesive surface 40B is flush with the third adhesive surface 31B. As a material for the resin layer 40, for example, a silicone resin may be exemplified. A temperature corresponding to an extreme value of a loss tangent within a temperature range of −150° C. or higher and 250° C. or lower of the resin layer 40 is −70° C. or lower, and preferably −100° C. or lower. The resin layer 40 may contain a filler such as alumina or aluminum nitride.

The adhesive layer 50 bonds the electrostatic chuck 30 onto the base plate 20. The adhesive layer 50, for example, conducts heat from the electrostatic chuck 30 to the base plate 20. That is, the adhesive layer 50 functions as an adhesive that bonds the base plate 20 and the electrostatic chuck 30, and also functions as a heat-conducting member.

The adhesive layer 50 has a first layer 51, a second layer 52, and a third layer 53. The first layer 51 is between the second layer 52 and the third layer 53. The second layer 52 is between the first layer 51 and the base plate 20, and the third layer is between the first layer 51 and the electrostatic chuck 30. For example, the first layer 51 is thicker than each of the second layer 52 and the third layer 53. For example, in the adhesive layer 50, the first layer 51 functions as a main adhesive layer, and the second layer 52 and the third layer 53 function as auxiliary adhesive layers.

As a material for the first layer 51, for example, a material with high thermal conductivity is preferable. As a material for the first layer 51, for example, a silicone adhesive may be exemplified. The first layer 51 may contain a filler such as alumina or aluminum nitride. The second layer 52 and the third layer 53 each include, for example, a surface modifier, a coupling agent, a resinous material, or the like that easily interact with the first layer 51. For example, the second layer 52 is applied and used on the first adhesive surface 20A, and the third layer 53 is applied and used on the second adhesive surface 30B.

In the substrate fixing device 10, as described above, the temperature corresponding to the extreme value of the loss tangent within the temperature range of −150° C. or higher and 250° C. or lower of the resin layer 40 is −70° C. or lower. Accordingly, even when the substrate fixing device 10 is used in a low-temperature environment of −40° C. or lower and is thermally contracted, the modulus of the resin layer 40 does not increase significantly, and the stress acting on the resin layer 40 does not increase to an extent at which cracks occur in the resin layer 40. Therefore, according to the substrate fixing device 10, the occurrence of cracks can be reduced and the uniformity of temperature on the substrate placement surface 30A can be improved.

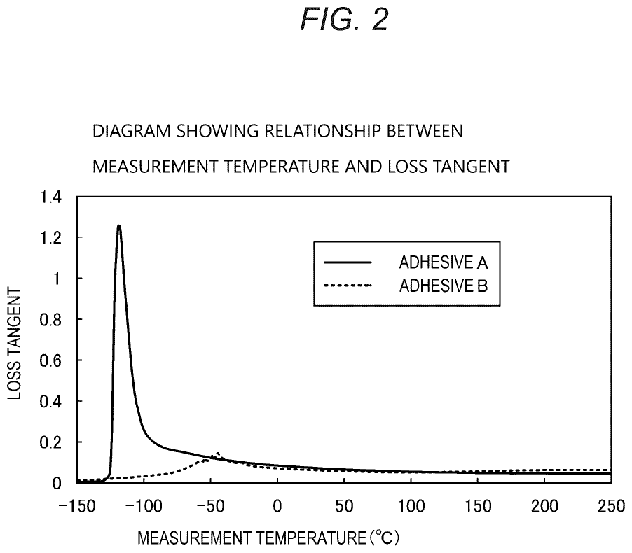

Here, the experiment conducted by the present inventors is described. In this experiment, test specimens were prepared using two types of adhesives (Adhesive A and Adhesive B), and their loss tangents were measured. A result thereof is shown in FIG. 2. Both Adhesive A and Adhesive B are silicone resins, but at least the structure of side chains differs between Adhesive A and Adhesive B. The loss tangent was measured by dynamic mechanical analysis (DMA). FIG. 2 is a diagram showing a relationship between a measurement temperature and a loss tangent.

The measurement conditions for the loss tangent are as follows.
Measurement device: DMA6100 (made by Hitachi High-Tech Science)
Measurement temperature range: −150° C. to 250° ° C.
Heating rate: 5° C./min
Measurement mode: tension
Measurement frequency: 1 Hz
Shape of test specimen: strip shape
Dimensions of test specimen: 15 mm (length)×15 mm (width)×0.1 mm to 1 mm (thickness)
Strain amplitude: 10 μm

In DMA, the complex modulus (G*), the storage modulus (G′), and the loss modulus (G″), which are expressed by the following equation (1), were measured.

G*=G′+G″i (1)

Here, the storage modulus (G′) is a value indicating the stiffness of a viscoelastic body, and the loss modulus (G″) is a value indicating the viscosity of a viscoelastic body.

In addition, in DMA, the loss tangent tan δ expressed by the following equation (2) was calculated from the storage modulus (G′) and loss modulus (G″). The loss tangent tan δ is a value indicating the degree of contribution of viscosity to a viscoelastic body. The temperature corresponding to the extreme value of the loss tangent tan δ is also referred to as the glass transition temperature (Tg).

tan δ=G″/G′ (2)

As shown in FIG. 2, the measurement data obtained from the test specimens shows that, for Adhesive A, the temperature corresponding to the extreme value of the loss tangent tan δ is about −120° C. (−70° C. or lower), and, for Adhesive B, the temperature corresponding to the extreme value of the loss tangent tan δ is about −50° C. In the above-described embodiment, Adhesive A may be used for the resin layer 40.

The present inventors calculated, through simulation, the stress acting on the resin layer 40 when Adhesive A was used for the resin layer 40, and the temperature of the base body 31 was −60° C., −80° C., and −100° C. The present inventors further calculated for comparison, through simulation, the stress acting on the resin layer when a resin layer using Adhesive B was provided instead of the resin layer 40 using Adhesive A, and the temperature of the base body 31 was −60° C., −80° C., and −100° C. These results are shown in Table 1.

TABLE 1

| | | |
|---|---|---|
| Temperature of | Stress (MPa) | Stress |

| electrostatic | Embodiment | Reference example | ratio |
|---|---|---|---|
| chuck (° C.) | (Adhesive A) | (Adhesive B) | (%) |
| −60 | 18.36 | 3346 | 0.5 |
| −80 | 30.54 | 6847 | 0.4 |
| −100 | 60.70 | 9790 | 0.6 |

As shown in Table 1, in the embodiment using Adhesive A, it was confirmed that the stress acting on the resin layer 40 became about 0.4% to 0.6% of the stress acting on the resin layer in the reference example using Adhesive B, that is, the stress ratio became extremely small, about 0.4% to 0.6%.

Note that the first layer 51 may be formed of an adhesive of the same type as that used for the resin layer 40. That is, the temperature corresponding to the extreme value of the loss tangent within the temperature range of −150° C. or higher and 250° C. or lower of the first layer 51 may be −70° C. or lower.

The fourth adhesive surface 40B of the resin layer 40 need not be flush with the third adhesive surface 31B of the base body 31. For example, the fourth adhesive surface 40B may have a convex shape bulging from the third adhesive surface 31B toward the first adhesive surface 20A.

Although the preferred embodiments have been described in detail, the present disclosure is not limited to the above-described embodiments, and a variety of changes and replacements can be made for the above-described embodiments without departing from the scope defined in the claims.

What is claimed is:

1. A substrate fixing device comprising:
a base plate having a first adhesive surface;
an electrostatic chuck configured to adsorb and hold a substrate and having a substrate placement surface on which the substrate is mounted and a second adhesive surface opposite to the substrate placement surface; and
an adhesive layer for bonding the first adhesive surface of the base plate and the second adhesive surface of the electrostatic chuck, wherein
the electrostatic chuck comprises
a base body having a third adhesive surface forming a portion of the second adhesive surface and having a recessed portion provided therein,
an electronic component accommodated in the recessed portion, and
a resin layer configured to seal the electronic component in the recessed portion and having a fourth adhesive surface forming another portion of the second adhesive surface, and
a temperature corresponding to an extreme value of a loss tangent within a temperature range of −150° C. or higher and 250° C. or lower of the resin layer is −70° C. or lower.

2. The substrate fixing device according to claim 1, wherein the temperature corresponding to the extreme value of the loss tangent within the temperature range of −150° C. or higher and 250° C. or lower of the resin layer is −100° C. or lower.

3. The substrate fixing device according to claim 1, wherein the adhesive layer comprises a layer in which a temperature corresponding to an extreme value of the loss tangent within a temperature range of −150° C. or higher and 250° C. or lower is −70° C. or lower.

4. The substrate fixing device according to claim 1, wherein the resin layer contains a filler.

5. The substrate fixing device according to claim 1, wherein
the electrostatic chuck comprises an electrode embedded in the base body and configured to adsorb the substrate, and
the electronic component is electrically connected to the electrode.

6. The substrate fixing device according to claim 1, wherein
the electrostatic chuck comprises a heating element embedded in the base body and configured to heat the substrate, and
the electronic component is electrically connected to the heating element.

7. The substrate fixing device according to claim 1, wherein the base plate comprises a cooling channel through which a cooling medium flows.

8. The substrate fixing device according to claim 1, wherein the third adhesive surface and the fourth adhesive surface are flush with each other.
